(19) United States
(12) Patent Application Publication
(10) Pub. No.: US 2009/0020307 A1
(43) Pub. Date: Jan. 22, 2009

(54) Methods and apparatuses for a magnetic decorator wall cover plate with the option to record decorating choices

(76) Inventor: Peter Roach, JR., Atlanta, GA (US)

Correspondence Address: Peter O. Roach Jr, 1150 Ives Ct, Atlanta, GA, 30319, US

(21) Appl. No.: 12/215,268

(22) Filed: Jun. 26, 2008

Related U.S. Application Data
(60) Provisional application No. 60/961,022, filed on Jul. 18, 2007.

(51) Int. Cl. H05K 13/04; H02G 3/14; G09F 3/00

(52) U.S. Cl. 174/66; 29/729; 40/299.01

(57) ABSTRACT

The invention provides methods and apparatuses for affixing a decorative cover over an existing switch plate by the use of magnets on the decorative that are positioned to attach to the screws used to hold the existing wall plate to the electrical fixture. The invention also discloses how to record decorating information, such as paint selection, on the decorative wall cover in order to removable store this information in the space where the decorations are installed.

### RELATED APPLICATIONS

The present application is related to the subject matter disclosed by and claims priority under 35 U.S.C. 119 to U.S. Provisional Patent Application Ser. No. 60/961,022, filed Jul. 18^{th} 2007, entitled “Methods and Apparatuses for a Magnetic Decorator Wall Cover Plate with the Option to Record Decorating Choices”. Applicant hereby incorporates by reference the complete disclosure of each of said referenced provisional patent applications.

### TECHNICAL FIELD

The present invention relates generally to the use of a magnetic device to add a decorative cover over an electrical junction cover plate and more specifically to the addition of the ability to record paint and decorating selections to the decorative cover.

### BACKGROUND OF THE INVENTION

The present invention is designed to alleviate the problem of misplacing or losing details of the selections made while decorating or remodeling a room or space. Examples of these decorating selections are the formulation of paint colors, installer/company used, vendor information, furniture choices, wall paper selection, ceiling covering, specific color or dye lot information, or other choices made about the construction or finishing of the space. For example, oftentimes after a room is painted, the paint container is disposed of, and the formula for the specific sheen, manufacturer, and color is lost. When touch up is needed the exact paint color is no longer known. This can cause the entire room to require repainting when a touch up might suffice.

Oftentimes a home or building owner may maintain paint or decorating records in a centralized repository. If maintained correctly, this will provide a record of the decorating choices for the space; however, this method has a deficiency of not being attached or associated with the space where the decorating choices are currently installed. For example a homeowner, selling their home, may not pass on the centralized repository or listing to the new homeowner or the existing homeowner may wish to keep the centralized repository to assist in future decorating choices thus depriving a new homeowner of this information.

There is also a desire for the supplier or installer of the decorating choice, such as a painter, to leave their name, contact number, or other relevant information in a permanent or semi-permanent location in the space where the decorating choice is installed. This would allow the installer or supplier to possibly gain future business from the advertisement in the space.

Further, it would be helpful if a sample of the paint were attached to an easily removable device to enable a home owner to be able to remove the device containing the paint samples and have access to the paint colors when making other decorating choices. This would enable a home owner to take the paint colors or other decorating choices with them when they were selecting furnishing, drapery, additional paint colors, carpet, or other decorating choices for the space. In addition it would be particularly helpful if this device containing the paint colors were located within the space where the paint colors were installed. This would provide a homeowner the capability of storing the paint colors in the space where the paint was installed. This would allow the homeowner to maintain a record of the paint choices in the most logical of all places—the room.

Others have disclosed decorative cover plates such as the ones disclosed in U.S. Pat. No. 5,456,373, or 3,953,933, or 3,987,928, or 4,800,239, or provisional application Ser. No. 11/258,788. All of these applications suffer from the problem of requiring the standard wall plate to be replaced in order to supply a base to affix a decorative cover plate. The problems associated with requiring the standard wall plate to be removed and/or replaced is the new protective cover plate will likely require UL certification and the new protective cover plate will likely be classified as an ‘electrical product’ when purchased and stocked in a normal retail outlet such as Home Depot or Lowes. Since it is likely this decorative cover plate will be treated by UL as an electrical device and thus further classified by retailers as being an electrical item, this means the decorative cover plate will likely be stocked in the electrical section of the retailer. Oftentimes when a space is repainted the wall plates are removed and the consumer may desire to replace these cover plates with new or decorative cover plates; however, since the previously disclosed inventions typically require the existing cover plate to be replaced, these type of decorative cover plates are treated as electrical items and they are stocked in the electrical section of the store and, more importantly, not typically stocked near the paint section. Oftentimes this is due to the departmentalization of the retailer. Since the paint department does not get credit for sale of an electrical item, the paint department is reluctant to stock and maintain a display that includes electrical items in the paint department floor space.

To alleviate these problems an easily removable decorative wall plate is needed that can be installed over the existing wall plate. This decorative wall plate can further be used to record of the paint or decorating selections for a specific room or area. The decorative wall plate with the decorating selections should be easily removable in order to be used to assist in making further decorating choices in a remote location away from the room or area. Previously there has not been a convenient method or apparatus of supplying a decorative wall plate that can be used to maintain these records in most rooms or areas without it detracting from the ascetics or without installing, special mounting plates or face plates to protect the electrical connections.

### DETAILED DESCRIPTION OF EXEMPLARY EMBODIMENTS

The present invention provides methods and apparatuses for mounting or affixing a decorative cover designed to hide the attaching hardware (screws) by using magnets attached to the decorative cover in order to attach the decorative cover wall plug cover, wall switch cover, CATV cover, Ethernet cover, blank wall plate, or any other similar covering designed, at least in part, to provide an aesthetically pleasing cover or protection for an electrical connection, access opening, cable run, or other similar opening in the wall or trim of a room or space (Hereafter referred to as ‘wall plate’). In addition this decorative cover plate can be optionally used to store paint samples, paint formulas, installer name, installer contact information, date of installation, or decorating choices, or other similar information on the reverse side of the decorative cover plate. The magnetic attachment mechanism has the additional benefit of allowing the decorative cover plate to be easily removed from the wall plate, without the use of tools, in order to take the decorative cover with the paint samples attached to assist in making additional decorating choices for the space.

The decorative cover plate allows for the attachment of a label, or portion of a label, that is typically printed and attached to the top of the paint can when paint colors are selected. By attaching this label it will allow the paint formulation information to be permanently or semi-permanently maintained as close as possible to the installation area thus reducing the risk of loss of this information. This label will also allow the installer or supplier of the decorating choice to place their contact details in the room where the decorating choice was located thus allowing the installer to advertise their services or products in close proximity to the location of their installation.

In the preferred embodiment, the information would be printed on a decal sticker or other such medium with an adhesive back or similar means to attach to the back of the magnetically attached decorative cover plate however, one skilled in the art, when using this disclosure, can see how the same intent can be obtained by other means of recording the information on the reverse of the magnetically attached decorative cover plate such as painting or printing the information directly onto the decorative cover, writing the information, placing a decal capable of being written, or by using some other type of affixed or removable medium to record the decorating choices.

The preferred location for the decorative cover containing the decorating information is the lighting switch for the room or area. Since there is usually at least one lighting switch in each room or area, the light switch is not commonly blocked by furniture/supplies/or other items, and the lighting switch plate is closer to eye level, this allows the wall plate to be easily removed and the information viewed without bending down or moving items to gain access. However, the decorative cover with the decorating information can be affixed to any of the wall plates in the without deviating from the intent of this disclosure.

Since the magnetically attached decorative cover plate attaches over the standard wall plate, this should negate the need for safety certifications for the decorative cover such as Underwriter's Laboratories or other safety concerns as the original wall plate remains installed to protect the electrical connections. The decorative cover plate and any decals or marking should not need to be certified since these would be protected from the electrical connections by the normal wall plate.

By using a decorative cover plate attached magnetically over a traditional wall plate it allows the decorative cover plate with the optional decorating information to be removed and transported away from the space in order to use this information in making other decorating selection for the space. For example, if the information contained samples of the paint used in the room, a housewife could take the decorative cover with her when making furniture, drapery, carpet, matching paint or other similar finishing selections. The standard wall plate would remain in place in order to cover any wall opening or electrical connections contained within and assure the safe operations of the wiring connections while the decorative cover was being used in this fashion.

Yet another enhancement to the present invention is to replace the screw(s) fastening the existing wall plate with magnetized screws. These magnetic screws would be polarized in such a fashion as to be attractive to the magnets attached to the decorative cover plate. This would increase the force in which the decorative cover plate was attached to the screws.

Yet a further enhancement to the present invention is to provide a concave area on the magnets attached to the decorative cover plate. This would allow the convex surface of typical screws provided with a standard wall plate to fit within the concave surface of the magnet. This would reduce the tendency of the magnets on decorative cover plate to rock on the convex surface of the screws thus providing a more secure method of attaching the decorative cover plate.

A still further enhancement to the present invention is to design the edges of the decorative cover plate to closely fit around a standard wall plate. This will reduce the tendency of the decorative cover plate to shift when the light switch was being turned on or off.

Yet a further enhancement to the present invention is to bevel the edges of the decorative cover plate. This would allow the cover plate to optically appear thinner than its actual size. The bevels on the side of the decorative cover plate could also be designed to contour the inner surface more precisely to the outer surface of a standard wall plate.

A further enhancement to the present invention is to bevel the edge around the inner opening for the light switch. This type of bevel allows a for an optically pleasing recessed area around the light switch in order to make the light switch easier to operate and access. Alternatively the recessed area does not require a bevel and can merely be recessed around the light switch opening.

Based on the foregoing, it can be seen that the present invention provides methods and apparatuses for mounting a decorative plate over an existing wall plate by utilizing magnets in the position to line up with the screws of the wall plate. Many other modifications, features and embodiments of the present invention will become evident to those of skill in the art. It should be appreciated, therefore, that many aspects of the present invention were described above by way of example only and are not intended as required or essential elements of the invention unless explicitly stated otherwise. Accordingly, it should be understood that the foregoing relates only to certain embodiments of the invention and that numerous changes may be made therein without departing from the spirit and scope of the invention as defined by the following claims. It should also be understood that the invention is not restricted to the illustrated embodiments and that various modifications can be made within the scope of the following claims.

### BRIEF DESCRIPTION OF THE DRAWINGS

FIG. 1 is a perspective of the component view of the solution

FIG. 2 is a perspective of the installation of the decorative cover plate

FIG. 3 is a perspective of the cover plate installed over the wall switch plate

FIG. 4 is a perspective of the optional markings for the reverse of wall switch plate

FIG. 5 is a perspective of the optional beveled cover plate showing interior bevel for switch access

FIG. 6 is a perspective of concave magnet designed to allow the convex head of a typical wall switch cover plate to fit properly

FIG. 7 is a perspective of a magnetic screw to increase magnetic attraction

### DESCRIPTION OF THE DRAWINGS

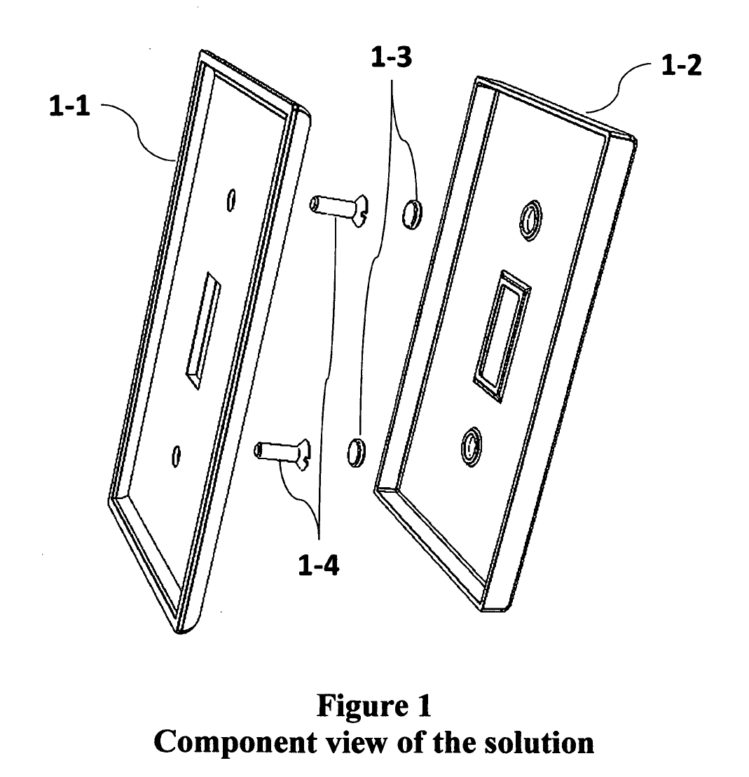

FIG. 1 is a perspective of a component view of the solution including 1-1 the wall switch cover plate that is normally found in a residential or business environment and typically attached over an electrical switch used for controlling devices such as lighting in a space. The wall switch cover plate shown is for a small rocker type switch; however, this invention can be used in conjunction with the larger decorative type switches, electrical outlet covers, coax cable covers, blank cover plates, high speed LAN connection cover plates, or other cover plates typically found in a residential or commercial space. One skilled in the art, using this disclosure, can see how this invention can be used with virtually any type of cover plate similar to a wall switch cover plate. Wall switch cover 1-1 is typically held in place by screws 1-4. Typically screws 14 are consistently located on a wall switch (not shown) so a wall switch cover plate 1-1 can be used with different manufacturers wall switches (not shown). In order to attach the decorative cover 1-2 over the wall switch cover plate 1-1 when it is installed using screws 1-4, the decorative cover 1-2 has magnets 1-3 attached to the decorative cover 1-2. In the preferred invention the magnets 1-3 are what are referred to as rare earth or super magnets and are often constructed from materials such as neodymium or samarium; however, one skilled in the art, when using this disclosure, can see how these magnets 1-3 can be constructed from other materials, can be different shapes, or can be located in different places provided the cover can be securely attached over the wall switch plate 1-1 using these magnets 1-3. These magnets 1-3 are affixed to the decorative cover 1-2 in a manner that allows the decorative cover 1-2 to be securely held over the wall switch cover plate 1-1 primarily by the force of the magnets 1-3 attaching to the screws 1-4; however, the decorative cover 1-2 may be further stabilized by conforming its inner surface shape to fit closely around the outer edge of the wall plate 1-1.

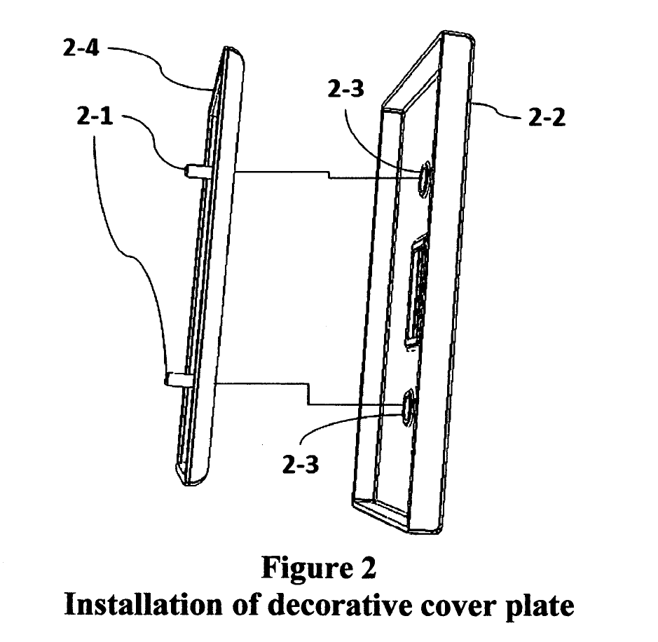

Turning now to FIG. 2. This illustrates the installation of the decorative cover 2-2 over the wall switch cover plate 2-4. The decorative cover 2-2 attaches to the screws 2-1 holding the wall switch cover plate 2-4 in place by using magnet 2-3 that are positioned in such a manner as to attach to the screws 2-1. In the preferred invention, the screws 2-1 are the typical screws provided when the wall switch cover plate 2-4 is purchased.

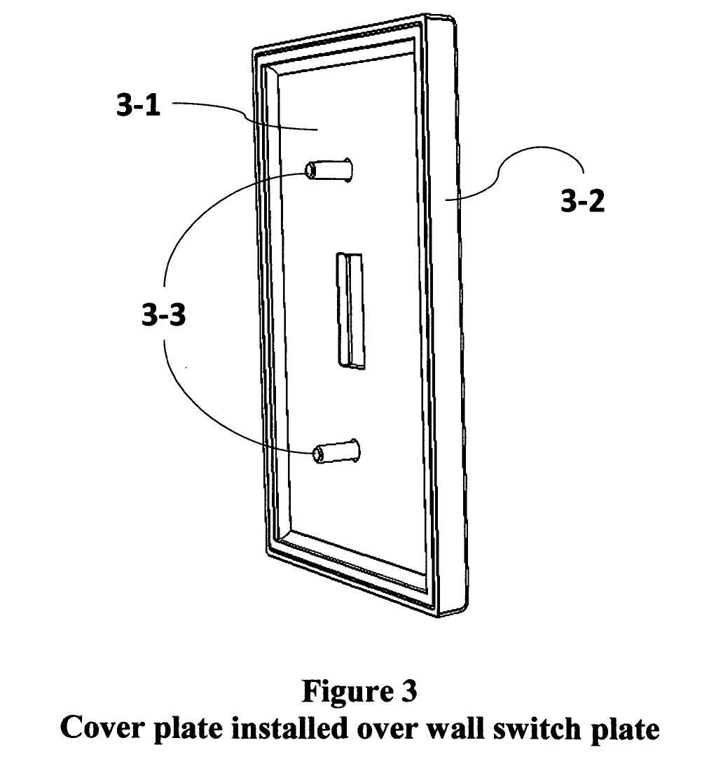

Turning now to FIG. 3. This illustrates the decorative cover plate 3-2 installed over the wall switch plate 3-1. It will be noted that the decorative cover plate 3-2 is designed in such a manner that the decorative cover plate 3-2 does not have excess space between the sides of the decorative cover plate 3-2 and the wall switch plate 3-1. This provides lateral and vertical stability for the decorative cover plate 3-2 when the decorative cover plate 3-2 is properly installed over the wall switch plate.

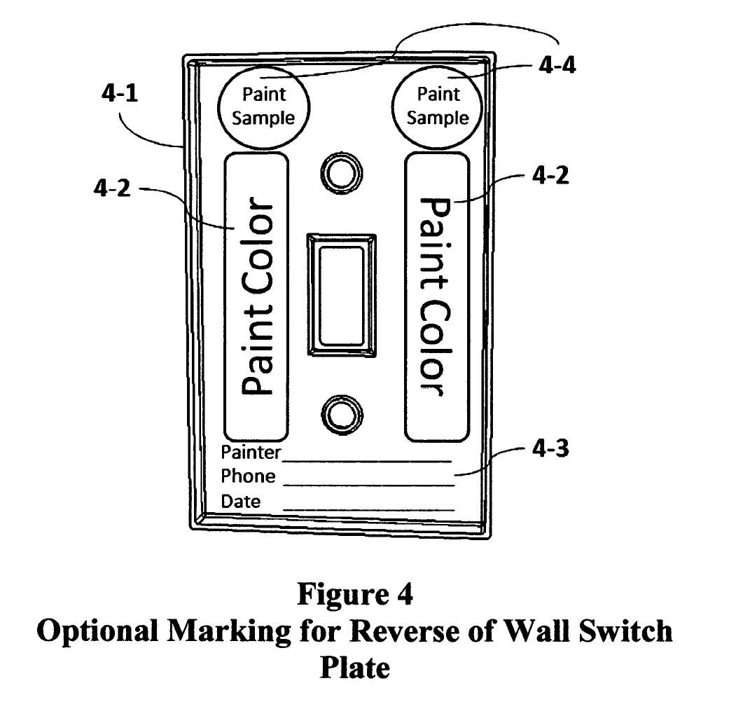

Turning now to FIG. 4. This is an illustration of the optional markings 4-2, 4-4, 4-3 on the reverse side of the decorative cover plate 4-1. These markings instruct a user, the technician mixing the paint, the installer of the paint, or other similar person how to install the decals indicating the paint color 4-2, where to place the paint samples 4-4, or where to place the paint installation information 4-3. Typically the paint samples would be installed by the technician (not shown) that mixed the paint. It is common for these technicians to place a sample of paint on the top of a paint can and at the same time they could easily place a sample on the decorative cover 4-1. One skilled in the art, when using this disclosure, can see how these optional markings 4-4, 4-2, 4-3 can be altered or relocated and still achieve the desired results of this disclosure. For example the paint formula can be placed on the decorative cover plate 4-1 by merely writing the paint formula instead of attaching a preprinted decal or the painter information can be included on a preprinted decal. These changes to the configuration of the optional markings 4-2, 4-3, 4-4 do not change the intent of the disclosure nor the intent of the invention.

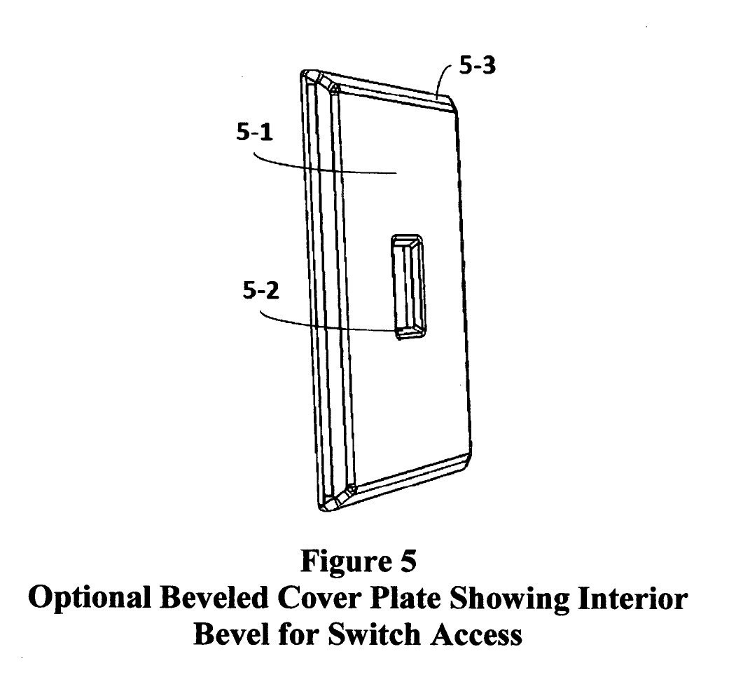

Turning now to FIG. 5. This is an illustration of an optional beveled decorative cover plate 5-1. This decorative cover plate 5-1 is designed with a bevel 5-3 around the outer edge of the decorative cover plate 5-1 in order to allow the decorative cover plate 5-1 to better conform to the design of a typical wall switch plate 2-1. This allows the inner surface of the decorative cover plate 5-1 to conform more closely to the wall switch plate 1-1 and to limit the movement of the decorative cover plate 5-1 when it is installed over the wall switch plate 1-1. One skilled in the art, when using this disclosure, can see how the same objective can be achieved by shaping the inner surface of the decorative cover to correspond with the outer surface of the wall plate to increase the stability of the decorative cover when installed over the wall plate. This illustration also shows a beveled edge 5-2 around the cut out for the electrical switch (not shown). This beveled edge 5-2 allows easier access to the wall switch (not shown).

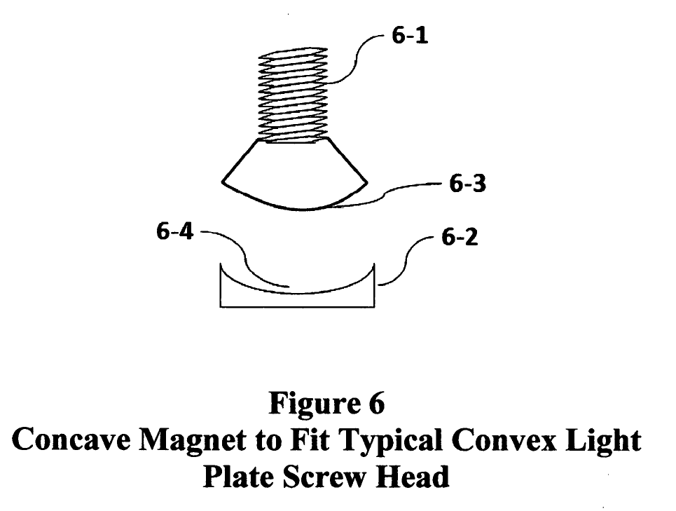

Turning now to FIG. 6, this illustrates a typical screw 6-1 provided with a wall switch cover plate 1-1. These types of screws 6-1 typically include a convex head 6-3 primarily for ascetic reasons. In order to allow the magnet 6-2 to better attach to the screws 6-1 it is a further aspect of the invention to place a concave recess 6-4 in the magnet 6-2 that corresponds to the convex 6-3 portion of the screw 6-1. This will allow the decorative cover plate 1-2 to minimize the potential for rocking on the convex 6-3 head of the screws 6-1.

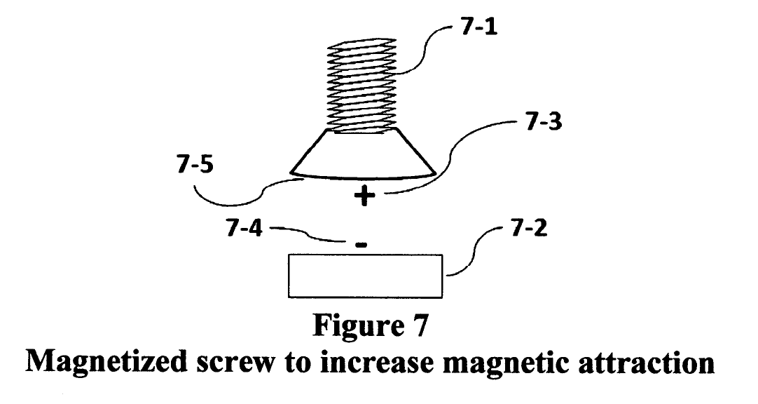

Turning now to FIG. 7, this illustrates a screw 7-1 that is used to attach the wall switch plate 1-1 to the wall switch (not shown) that has been magnetized 7-3 in a different polarity to the surface of the magnet 7-2 and is designed to hold the decorative plate 1-2 securely in place. This increased magnet attraction 7-3, 7-4 will be used to better secure the decorative plate in place. Also, this illustration provides for a flat head 7-5 for the screw 7-1. This screw 7-1 would typically be supplied with a decorative cover 1-2 and would be designed to replace the normal convex screws 6-1 supplied with standard wall switch plate 1-1. This would allow for a flat head magnet 7-2 to be used to attach the decorative switch plate 1-2. It is also possible to magnetize only the replacement screws and to supply a ferrous metal plate in place of the magnets on the decorative wall plate. This alternative implementation would achieve the same functionality as described herein.

One skilled in the art, when considering this disclosure, can determine how the functionality illustrated in the figures and described in the disclosure can be changed and adapted by adding bevels, supplying the wall switch plate 1-1 in the same packaging with the decorative cover plate 1-2, changing the ascetics, removing or adapting features, or similar functions without impacting the overall intent or functionality of the invention disclosed. One skilled in the art, when considering this disclosure, can also determine how this invention can be applied to other cover plates typically found in a residential or commercial space. It can also be seen how this disclosure improves on prior art in providing an easily removable decorative cover plate that is magnetically attached to the screws of a wall switch plate while optionally being capable of storing decorating choices.

Other modifications, features, and embodiments of the present invention will become evident to those of skill in the art. It should be appreciated, therefore, that many aspects of the present invention were described above by way of example only and are not intended as required or essential elements of the invention unless explicitly stated otherwise. Accordingly, it should be understood that the foregoing relates only to certain embodiments of the invention and that numerous changes may be made therein without departing from the spirit and scope of the invention as defined by the following claims. It should also be understood that the invention is not restricted to the illustrated embodiments and that various modifications can be made within the scope of the following claims.

What is claimed is:

1. A method of attaching a decorative cover plate over a standard wall plate by utilizing magnets positioned in a manner to attach to at least one the screw used to affix standard wall plate in place.

2. The method of claim 1 where the decorative cover plate is designed to be able to store decorating information on the side of the decorative cover plate positioned closest to the standard wall switch plate when the decorative cover plate is properly installed.

3. The method of claim 1 where the decorative cover includes a bevel surrounding the opening for a light switch.

4. The method of claim 1 the magnets on the decorative cover are shaped in order to fit with the convex screws supplied with a standard wall plate.

5. The method of claim 1 where the screws supplied with a standard wall plate are substituted with magnetized screws.

6. The method of claim 5 where the substituted screws are polarized in a manner to increase their attraction to the magnets mounted on the decorative cover plate.

7. The method of claim 1 where the decorative cover plate is designed to closely fit the outer dimensions of the wall switch plate in order to minimize the movement of the decorative cover plate when properly installed.

8. An apparatus of a decorative wall plate
a. including a magnetic means of attachment
b. where the magnetic means are oriented in a manner corresponding with the position of screws typically utilized to attach a standard wall cover plate to an electrical fixture.

9. The apparatus of claim 8 where the decorative cover plate is designed to be able to store decorating information on the reverse side of the decorative cover plate.

10. The apparatus of claim 8 where the decorative cover includes a bevel surrounding the opening for a light switch.

11. The apparatus of claim 8 where the magnets attached to the decorative cover are concaved in order to better fit with the convex screws supplied with a standard wall plate.

12. The apparatus of claim 8 where the screws supplied with a standard wall plate are substituted with magnetized screws.

13. The apparatus of claim 12 where the substituted screws are polarized in a manner to increase their attraction to the magnets mounted on the decorative cover plate.

14. The apparatus of claim 8 where the decorative cover plate is designed to closely fit the outer dimensions of the wall switch plate in order to minimize the movement of the decorative cover plate when properly installed.

15. The apparatus of claim 9 where the decorating information includes at least one paint sample.

16. The method of installing a paint sample upon a decorative cover plate that is designed with magnets positioned in a manner to attach the decorative cover plate to the screws typically used to attach a standard wall cover plate to an electrical fixture.

17. The method of claim 16 where the paint formulas are recorded on the decorative cover plate.

18. The method of claim 17 where a decal is used to record the paint formulas on the decorative cover plate.

19. The method of claim 16 where the installer's contact information is recorded on the decorative cover plate.

20. The method of claim 16 where the decorative cover plate is marked in such a manner as to indicate decorating information can be recorded on the decorative cover plate.
